(19) United States
(12) Patent Application Publication
(10) Pub. No.: US 2015/0194623 A1
(43) Pub. Date: Jul. 9, 2015

(54) ORGANIC LIGHT-EMITTING DEVICE AND METHOD OF MANUFACTURING THE SAME

(71) Applicant: SAMSUNG DISPLAY CO., LTD., Yongin-City (KR)

(72) Inventors: Sang-Woo PYO, Yongin-City (KR); Ha-Jin SONG, Yongin-City (KR); Byeong-Wook YOO, Yongin-City (KR); Ji-Hwan YOON, Yongin-City (KR); Kyul HAN, Yongin-City (KR)

(73) Assignee: SAMSUNG DISPLAY CO., LTD., Yongin-City (KR)

(21) Appl. No.: 14/253,157

(22) Filed: Apr. 15, 2014

(30) Foreign Application Priority Data
Jan. 9, 2014 (KR) 10-2014-0003058

(51) Int. Cl. H01L 51/50; H01L 51/00

(52) U.S. Cl. CPC H01L 51/5036; H01L 51/0002

(57) ABSTRACT

An organic light-emitting device and a method of manufacturing the same, including a substrate; a plurality of first electrodes on the substrate in a first to third light-emitting region; a first common layer on the substrate, the first common layer covering the plurality of first electrodes; a first light-emitting layer in the first light-emitting region and on the first common layer; a second light-emitting layer in the second light-emitting region and on the first common layer; a third light-emitting layer in the third light-emitting region and on the first common layer; a second common layer that is commonly disposed on the first light-emitting layer, the second light-emitting layer, and the third light-emitting layer; a second electrode on the second common layer; and an auxiliary layer that is commonly disposed only in the first light-emitting region and the second light-emitting region between the first common layer and the second common layer.

### CROSS-REFERENCE TO RELATED APPLICATION

Korean Patent Application No. 10-2014-0003058, filed on Jan. 9, 2014, in the Korean Intellectual Property Office, and entitled: “Organic Light-Emitting Device and Method of Manufacturing the Same,” is incorporated by reference herein in its entirety.

### BACKGROUND

1. Field

Embodiments relate to an organic light-emitting device and a method of manufacturing the same.

2. Description of the Related Art

Organic light-emitting devices that use a self-emissive material that emits light in response to a voltage may have advantages of improved brightness, a high contrast ratio, many colors, a wide viewing angle, a fast response time, and a low operating voltage.

An organic light-emitting device may include an organic light-emitting layer that is between an anode and a cathode. When a voltage is applied, holes and electrons may be respectively injected from the anode and the cathode into the organic light-emitting layer. The injected holes and electrons may cause an electron transfer between adjacent molecules in the organic light-emitting layer and move to opposite electrodes. When an electron and a hole are recombined in a certain molecule, a molecular exciton having a high-energy excited state may be formed. Light may be emitted when the molecular exciton returns to a low-energy ground state.

### SUMMARY

Embodiments are directed to an organic light-emitting device and a method of manufacturing the same.

The embodiments may be realized by providing an organic light-emitting device including a substrate; a plurality of first electrodes on the substrate in a first light-emitting region, a second light-emitting region, and a third light-emitting region; a first common layer on the substrate, the first common layer covering the plurality of first electrodes; a first light-emitting layer in the first light-emitting region and on the first common layer; a second light-emitting layer in the second light-emitting region and on the first common layer; a third light-emitting layer in the third light-emitting region and on the first common layer; a second common layer that is commonly disposed on the first light-emitting layer, the second light-emitting layer, and the third light-emitting layer; a second electrode on the second common layer; and an auxiliary layer that is commonly disposed only in the first light-emitting region and the second light-emitting region between the first common layer and the second common layer.

The auxiliary layer may be between the first light-emitting layer and the first common layer and between the second light-emitting layer and the first common layer.

The auxiliary layer may be between the first light-emitting layer and the second common layer and between the second light-emitting layer and the second common layer.

The third light-emitting layer and the auxiliary layer may be commonly formed on the same layer.

The third light-emitting layer and the auxiliary layer that are commonly formed may be disposed between the first, second light-emitting layers and the first common layer.

The third light-emitting layer and the auxiliary layer that are commonly formed may be disposed between the first, second light-emitting layers and the third common layer.

The organic light-emitting device may further include a common auxiliary layer on the first common layer, the common auxiliary electrode being between the first common layer and the first to third light-emitting layers.

The organic light-emitting device may further include a common auxiliary layer under the second common layer, the common auxiliary electrode being between the second common layer and the first to third light-emitting layers.

The first light-emitting layer and the second light-emitting layer may have the same thickness.

The first light-emitting region may be a blue light-emitting region, the second light-emitting region may be a red light-emitting region, and the third light-emitting region may be a green light-emitting region.

The embodiments may be realized by providing a method of manufacturing an organic light-emitting device, the method including providing a substrate; forming a plurality of first electrodes on the substrate in a first light-emitting region, a second light-emitting region, and a third light-emitting region of the substrate; forming a first common layer on the substrate such that the first common layer covers the first electrodes; forming a first light-emitting layer in the first light-emitting region and on the first common layer using a first mask; forming a second light-emitting layer in the second light-emitting region and on the first common layer using a second mask; forming a third light-emitting layer in the third light-emitting region and on the first common layer using a third mask; commonly forming a second common layer on the first light-emitting layer, the second light-emitting layer, and the third light-emitting layer; forming a second electrode on the second common layer; and commonly forming an auxiliary layer between the first common layer and the second common layer and only in the first light-emitting region and the second light-emitting region using a fourth mask.

The auxiliary layer may be formed between the first light-emitting layer and the first common layer and between the second light-emitting layer and the first common layer.

The auxiliary layer may be formed between the first light-emitting layer and the second common layer and between the second light-emitting layer and the second common layer.

The method may further include forming a common auxiliary layer after forming the first common layer such that the common auxiliary layer is between the first common layer and the first to third light-emitting layers.

The method may further include forming a common auxiliary layer prior to forming the second common layer such that the common auxiliary layer is between the second common layer and the first to third light-emitting layers.

The first light-emitting region may be a blue light-emitting region, the second light-emitting region may be a red light-emitting region, and the third light-emitting region may be a green light-emitting region.

The embodiments may be realized by providing a method of manufacturing an organic light-emitting device, the method including providing a substrate; forming a plurality of first electrodes on the substrate in a first light-emitting region, a second light-emitting region, and a third light-emitting region; forming a first common layer on the substrate such that the first common layer covers the first electrodes; forming a first light-emitting layer in the first light-emitting region and on the first common layer using a first mask; forming a second light-emitting layer in the second light-emitting region and on the first common layer using a second mask; commonly forming a second common layer on the first light-emitting layer and the second light-emitting layer; forming a second electrode on the second common layer; and commonly forming a common third light-emitting layer in the first light-emitting region, the second light-emitting region, and the third light-emitting region between the first common layer and the second common layer.

The common third light-emitting layer may be formed prior to forming the first light-emitting layer and the second light-emitting layer such that the common third light-emitting layer is between the first common layer and the first light-emitting layer and between the first common layer and the second light-emitting layer.

The common third light-emitting layer may be formed after forming the first light-emitting layer and the second light-emitting layer such that the common third light-emitting layer is between the second common layer and the first light-emitting layer and between the second common layer and the second light-emitting layer.

The method may further include forming a common auxiliary layer after forming the first common layer such that the common auxiliary layer is between the first common layer and the common third light-emitting layer.

The method may further include forming a common auxiliary layer prior to forming the second common layer such that the common auxiliary layer is between the second common layer and the common third light-emitting layer.

The first light-emitting region may be a blue light-emitting region, the second light-emitting region may be a red light-emitting region, and the third light-emitting region may be a green light-emitting region.

### BRIEF DESCRIPTION OF THE DRAWINGS

Features will be apparent to those of skill in the art by describing in detail exemplary embodiments with reference to the attached drawings in which:

FIG. 1 illustrates a cross-sectional view of an organic light-emitting device according to an embodiment of the present invention;

FIGS. 2 through 7 illustrate cross-sectional views of stages in a method of manufacturing the organic light-emitting device of FIG. 1;

FIGS. 8 through 12 illustrate cross-sectional views of organic light-emitting devices according to other embodiments;

FIG. 13 illustrates a cross-sectional view illustrating an organic light-emitting device according to another embodiment of the present invention;

FIGS. 14 through 17 illustrate cross-sectional views of stages in a method of manufacturing the organic light-emitting device of FIG. 13; and

FIGS. 18 through 22 illustrate cross-sectional views of organic light-emitting devices according to other embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

As used herein, the term “and/or” includes any and all combinations of one or more of the associated listed items. Expressions such as “at least one of,” when preceding a list of elements, modify the entire list of elements and do not modify the individual elements of the list.

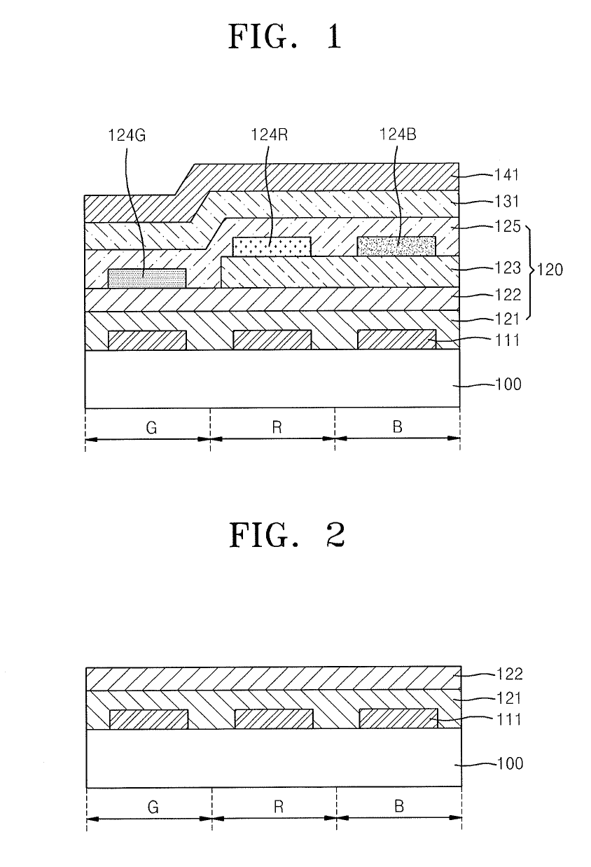

FIG. 1 illustrates a cross-sectional view of an organic light-emitting device according to an embodiment. FIGS. 2 through 7 illustrate cross-sectional views of stages in a method of manufacturing the organic light-emitting device of FIG. 1.

Referring to FIGS. 1 through 7, a first light-emitting region B, a second light-emitting region R, and a third light-emitting region G may be divided on a substrate 100. The first light-emitting region B may be a region that is included in a blue sub-pixel and emits blue light. The second light-emitting region R may be a region that is included in a red sub-pixel and emits red light. The third light-emitting region G may be a region that is included in a green sub-pixel and emits green light. A plurality of the first light-emitting regions B, the second light-emitting regions R, and the third light-emitting regions G may be divided on the substrate 100. The following will be explained for convenience of explanation using the illustrative example that one light-emitting region B, one second light-emitting region R, and one third light-emitting region G are divided over the substrate 100. Elements of the organic light-emitting device will now be explained in accordance with operations of manufacturing the organic light-emitting device of FIG. 1.

The substrate 100 may have a top surface that is flat, and may be formed of, e.g., a transparent insulating material. For example, the substrate 100 may be formed of glass. In an implementation, the substrate 100 may be formed of, e.g., a plastic material such as polyethersulphone (PES), or polyacrylate (PAR). The substrate 100 may be formed of, e.g., an opaque material such as a metal or a carbon fiber. In an implementation, in order to realize a flexible apparatus, the substrate 100 may be formed of, e.g., a flexible plastic such as a polyimide (PI) film.

The organic light-emitting device may be on the substrate 100. The organic light-emitting device may include a first electrode 111 on the substrate 100, an intermediate layer 120 on the first electrode 111, a second electrode 131 on the intermediate layer 120 and that faces the first electrode 111, and a capping layer 141 on the second electrode 131.

The first electrode 111 may be disposed on the substrate 100, and may be independently patterned in each of the first light-emitting region B, the second light-emitting region R, and the third light-emitting region G. The first electrode 111 may be a reflective electrode, and may include a reflective layer including, e.g., silver (Ag), magnesium (Mg), aluminum (Al), platinum (Pt), palladium (Pd), gold (Au), nickel (Ni), neodymium (Nd), iridium (Ir), chromium (Cr), or a compound thereof, and a transparent or semi-transparent electrode layer that is formed on the reflective layer.

The transparent or semi-transparent electrode layer may include any one of e.g., indium tin oxide (ITO), indium zinc oxide (IZO), zinc oxide (ZnO), indium oxide (In₂O₃), indium gallium oxide (IGO), or aluminum zinc oxide (AZO).

The intermediate layer 120 may be disposed on the first electrode 111. The intermediate layer 120 may include a first common layer 121 (that is commonly formed in the first through third light-emitting regions B, R, and G, e.g., continuously extends across all of the first through third light-emitting regions B, R, and G), a common auxiliary layer 122 (on the first common layer 121), a third light-emitting layer 124G (on the common auxiliary layer 122 to correspond to or in the third light-emitting region G), an auxiliary layer 123 (on the common auxiliary layer 122 to correspond to or in the first light-emitting region B and the second light-emitting region R), a first light-emitting layer 124B (on the auxiliary layer 123 to correspond to or in the first light-emitting region B), a second light-emitting layer 124R (on the auxiliary layer 123 to correspond to or in the second light-emitting region R), and a second common layer 125 (that covers all of the first light-emitting layer 124B, the second light-emitting layer 124R, and the third light-emitting layer 124G).

When the first electrode 111 is formed of a material having a work function higher than that of the second electrode 131, and thus functions as an anode, the first common layer 121 may be a hole injection layer (HIL), a hole transport layer (HTL), or a hole injection transport layer (HITL). The HIL may facilitate hole injection into a light-emitting layer, and may use, e.g., N,N-diphenyl-N,N-bis-[4-(phenyl-m-tolyl-amino)-phenyl]-biphenyl-4,4′-diamine (DNTPD), 4,4′,4″-tris(3-methylphenylphenylamino)triphenylamine (m-MTDATA), 4,4′4″-tris(N,N-diphenylamino)triphenylamine (TDATA), 4,4′,4″-tris{N,-(2-naphthyl)-N-phenylamino}-triphenylamine (2T-NATA), N,N′-di(-naphthyl)-N,N′-diphenylbenzidine (NPB), Poly(3,4-ethylenedioxythiophene)/Poly(4-styrenesulfonate (PEDOT/PSS), Polyaniline/Dodecylbenzenesulfonic acid (Pani/DBSA), Polyaniline/Camphor sulfonicacid (Pani/CSA), or Polyaniline/Poly(4-styrenesulfonate) (PANI/PSS).

The HTL may enable the injected hole to be easily transported to the light-emitting layer, and may use, e.g., N,N′-bis(3-methylphenyl)-N,N′-diphenyl-[1,1-biphenyl]-4,4′-diamine (TPD), 4,4′-bis[N-(1-naphthyl)-N-phenylamino]biphenyl (NPB), or 4,4′,4″-tris(N-carbazolyl)triphenylamine (TCTA). The first common layer 121 may be commonly formed on the entire substrate 100 to cover the first electrode 111 without using a fine metal mask (FMM), and may be formed by using any of various methods such as vacuum deposition, spin-coating, or casting.

Referring to FIG. 2, the common auxiliary layer 122 may be formed on the first common layer 121. The common auxiliary layer 122 may be, e.g., an HTL or an HITL. Accordingly, the common auxiliary layer 122 may use or may include a suitable material for an HTL or an HITL. The common auxiliary layer 122 may be commonly formed on the entire substrate 100 to cover the first common layer 121 without using an FMM, and may be formed by using any of various methods such as vacuum deposition, spin-coating, or casting. In an implementation, the common auxiliary layer 122 may have a thickness of, e.g., about 400 Å to about 600 Å.

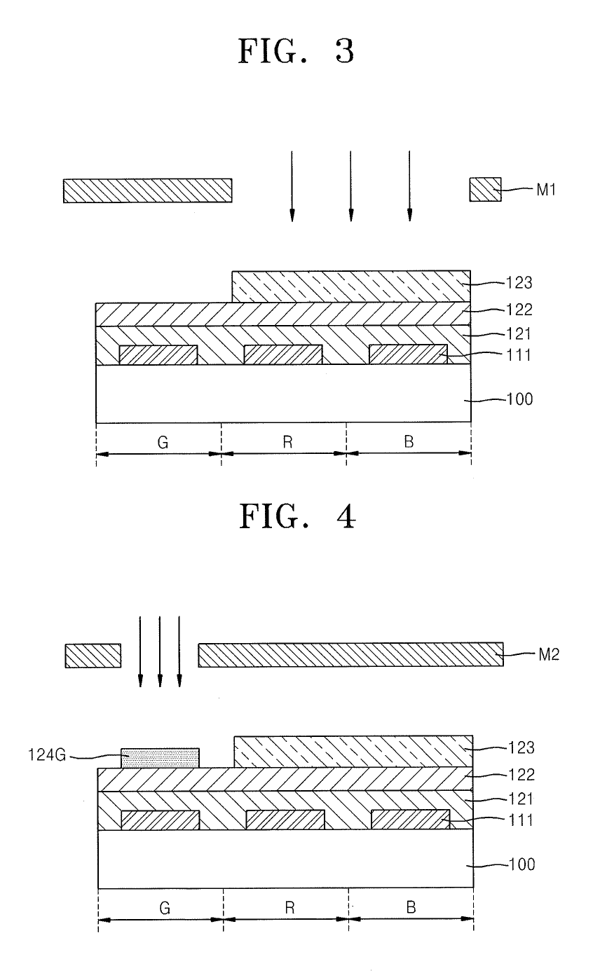

Referring to FIG. 3, the auxiliary layer 123 may be formed in the first light-emitting region B and the second light-emitting region R over or on the first common layer 121. The auxiliary layer 123 may be, e.g., an HTL or an HITL. Accordingly, the auxiliary layer 123 may use or may include a suitable material for an HTL or an HITL. For example, the auxiliary layer 123 may be formed only in the first light-emitting region B and the second light-emitting region R by using vacuum deposition or spin-coating. In an implementation, the auxiliary layer may have a thickness of, e.g., about 300 Å to about 500 Å.

Referring to FIG. 4, the third light-emitting layer 124G may be formed in the third light-emitting region G over or on the first common layer 121. The third light-emitting layer 124G may be a light-emitting layer that emits green light. The third light-emitting layer 124G may include a green host and a green dopant. Examples of the green host may include Alq3, 4,4′-N,N′-dicabazole-biphenyl (CBP), poly(n-vinylcabazole) (PVK), 9,10-di(naphthalene-2-yl)anthracene (ADN), TCTA, 1,3,5-tris(N-phenylbenzimidazole-2-yl)benzene (TPBI), 3-tert-butyl-9,10-di(naphth-2-yl)anthracene (TBADN), E3, and distyrylarylene (DSA). Examples of the green dopant may include tris(2-phenylpyridine) iridium (Ir(ppy)₃), Bis(2-phenylpyridine)(Acetylacetonato)iridium(III) (Ir(ppy)₂(acac)), tris(2-(4-tolyl)phenylpiridine)iridium (Ir(mppy)₃), and 10-(2-benzothiazolyl)-1,1,7,7-tetramethyl-2,3,6,7-tetrahydro-1H,5H,11H-[1]benzopyrano [6,7,8-ij]-quinolizin-11-one (C545T). The third light-emitting layer 124G may be formed only in the third light-emitting region G by using vacuum deposition using a second FMM M2. In an implementation, the third light-emitting layer 124G may have a thickness of, e.g., about 200 Å to about 400 Å.

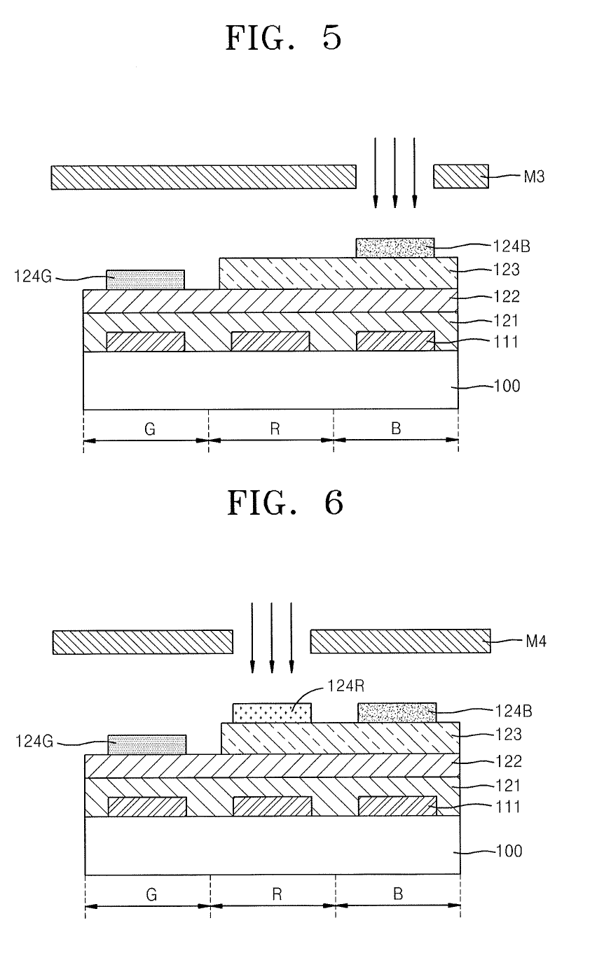

Referring to FIG. 5, the first light-emitting layer 124B may be formed in the first light-emitting region B over or on the auxiliary layer 123. The first light-emitting layer 124B may be a light-emitting layer that emits blue light. The first light-emitting layer 124B may include a blue host and a blue dopant. Examples of the blue host may include Alq3, CBP, PVK, ADN, TCTA, TPBI, TBADN, E3, and DSA. Examples of the blue dopant may include F2Irpic, (F2ppy)₂Ir(tmd), Ir(dfppz)₃, ter-fluorene, 4,4′-bis(4-diphenylaminostyryl)biphenyl (DPAVBi), and 2,5,8,11-tetra-t-butylperylene (TBPe). The first light-emitting layer 124B may be formed only in the first light-emitting region B by using vacuum deposition using a third FMM M3. In an implementation, the first light-emitting layer 124B may have a thickness of, e.g., about 200 Å to about 400 Å.

Referring to FIG. 6, the second light-emitting layer 124R may be formed in the second light-emitting region R over or on the auxiliary layer 123. The second light-emitting layer 124R may be a light-emitting layer that emits red light. The second light-emitting layer 124R may include a red host and a red dopant. Examples of the red host may include Alq3, CBP, PVK, ADN, TCTA, TPBI, TBADN, E3, and DSA, like the blue host. Examples of the red dopant may include Ir(piq)₃, Btp2Ir(acac), Ir(piq)₂(acac), Ir(2-phq)₂(acac), Ir(2-phq)3, Ir(flq)₂(acac), Ir(fliq)₂(acac), 4-(dicyanomethylene)-2-methyl-6-p-(dimethylamino) styryl-4H-pyran (DCM), and 4-(Dicyanomethylene)-2-tert-butyl-6-(1,1,7,7-tetramethyljulolidin-4-yl-vinyl)-4H-pyran (DCJTB).

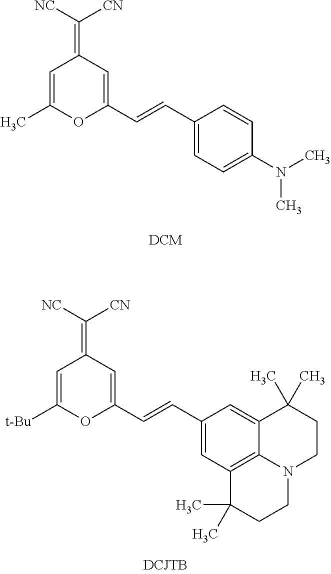

The second light-emitting layer 124R may be formed only in the second light-emitting region R by using vacuum deposition. In an implementation, the second light-emitting layer 124R may have a thickness of, e.g., about 200 Å to about 400 Å.

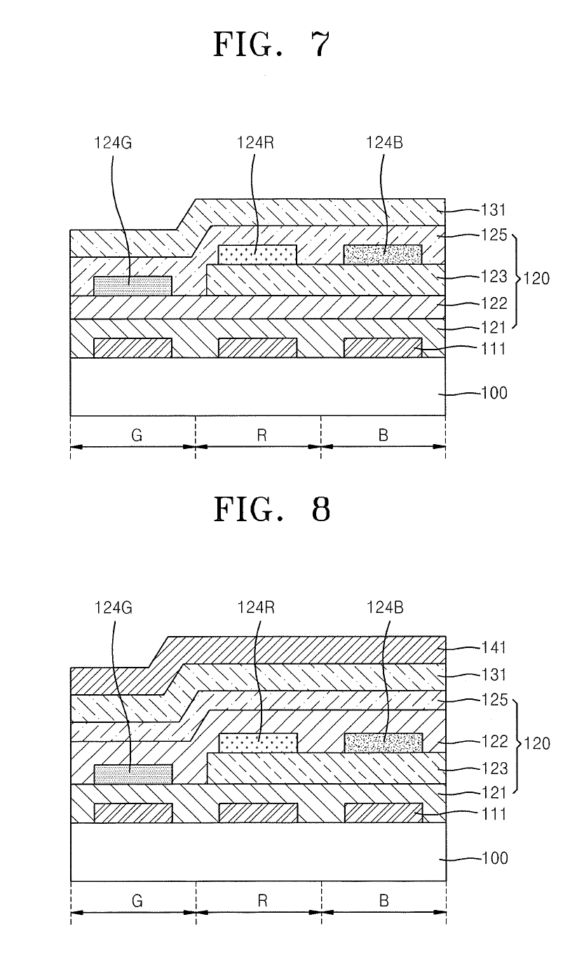

Referring to FIG. 7, the second common layer 125 may be formed to cover the first light-emitting layer 124B, the second light-emitting layer 124R, and the third light-emitting layer 124G. When the second electrode 131 functions as a cathode, the second common layer 125 may be, e.g., an electron injection layer (EIL), an electron transport layer (ETL), or an electron injection transport layer (EITL). The EIL may enable electrons to be easily injected into a light-emitting layer, and may use or may include, e.g., a suitable material for an EIL. For example, the EIL may include LiF, NaCl, CsF, Li₂O, or BaO. The ETL may enable the injected electrons to be easily transported to the light-emitting layer, and may use or may include a suitable material, e.g., Alq3, 2,9-Dimethyl-4,7-diphenyl-1,10-phenanthroline (BCP), 4,7-Diphenyl-1,10-phenanthroline (Bphen), 3-(4-Biphenylyl)-4-phenyl-5-tert-butylphenyl-1,2,4-triazole (TAZ), 4-(Naphthalen-1-yl)-3,5-diphenyl-4H-1,2,4-triazole (NTAZ), 2-(4-Biphenylyl)-5-(4-tert-butylphenyl)-1,3,4-oxadiazole (tBu-PBD), beryllium bis(benzoquinolin-10-olate (Bebq₂), or 9,10-di(naphthalene-2-yl)anthrascene (ADN). The second common layer 125 may be commonly formed on the entire substrate 100 to cover light-emitting layers without using an FMM, and may be formed by using any of various methods such as vacuum deposition, spin-coating, or casting.

The second electrode 131 may be formed or disposed on the intermediate layer 120. The second electrode 131 may be, e.g., a semi-transparent electrode. The second electrode 131 may include, e.g., at least one material selected from the group of Ag, Al, Mg, lithium (Li), calcium (Ca), copper (Cu), LiF/Ca, LiF/Al, Mg:Ag, and Ca:Ag. The second electrode 131 may be formed as a thin film having a thickness of several nanometers (nm) to tens of nm.

In the present embodiment, the organic light-emitting device may be a top-emission organic light-emitting device for emitting light away from the substrate 100.

Light that is emitted from a light-emitting layer may travel in all directions. In this case, light traveling toward the first electrode 111 may be reflected back toward the second electrode 131. Part of light traveling toward the second electrode 131 may be reflected by the second electrode 131 (that is a semi-transmissive electrode) back to the first electrode 111, and part of the light traveling toward the second electrode 131 may travel away from the substrate 100 to be emitted to the outside.

For example, part of light that is emitted by a light-emitting layer may reciprocate between the first electrode 111 and the second electrode 131, and only light having a specific wavelength (e.g., that satisfies a constructive interference condition) may be amplified and may be emitted or transmitted away from the substrate 100. The first electrode 111 (e.g., a reflective electrode) and the second electrode 131 (e.g., a semi-transmissive electrode) may form a microcavity, thereby improving light efficiency and color purity.

The intermediate layer 120 (that is included in the organic light-emitting device) may include a resonance distance adjusting layer for adjusting a distance between the first electrode 111 and the second electrode 131, and the first common layer 121, the second common layer 125, the common auxiliary layer 122, and the auxiliary layer 123 may function as the resonance distance adjusting layer. Light-emitting layers emit red, green, and blue light each having a relatively wide wavelength width, and the light is changed to light having a narrow wavelength width due to the microcavity, to be emitted to the outside. In this case, a wavelength of the light that is emitted to the outside may be determined according to a distance between the first electrode 111 and the second electrode 131, and thus light having a desired wavelength may be emitted by adjusting a distance between the first electrode 111 and the second electrode 131 by using the resonance distance adjusting layer.

The organic light-emitting device may apply secondary resonance to red light and green light, and may apply tertiary resonance to blue light. The term ‘secondary resonance’ may refer to resonance at a natural frequency of 2, and a wavelength that has one node may be generated in a corresponding resonance distance. Also, the term ‘tertiary resonance’ may refer to resonance at a natural frequency of 3, and a wavelength that has two nodes is generated in a corresponding resonance distance.

When the same natural frequency (e.g., a frequency of 1) is applied to red light, green light, and blue light, the blue light (having a shorter wavelength) may have a shortest resonance distance, and the red light (having a longer wavelength) may have a longest resonance distance. When different natural frequencies are applied to pieces or portions of light having different colors, very similar resonance distances may be formed for pieces or portions of light having different wavelengths.

Referring to FIG. 1, a natural frequency of 2 may be applied to red light, and a natural frequency of 3 may be applied to blue light. Also, red light (that has a wavelength greater than that of conventional or other red light) may be determined to be emitted in accordance with digital cinema initiatives (DCI) that is a standard for digital cinema systems. For example, the same resonance distance may be formed for the red light and the blue light.

Accordingly, referring FIG. 1, distances between the first electrode 111 and the second electrode 131 in a red light-emitting region and a blue light-emitting region may be the same. For example, resonance distance adjusting layers having the same thickness may be provided for the red light and the blue light. Accordingly, thicknesses of the red light-emitting layer (the second light-emitting layer 124R in FIG. 1) and the blue light-emitting layer (the first light-emitting layer 124B in FIG. 1) may be the same, and the auxiliary layer 123 may be commonly provided to have the same thickness in the second light-emitting region R and the first light-emitting region B.

In the present embodiment, the auxiliary layer 123 (for adjusting a resonance distance) may not be separately provided in each of the first light-emitting region B, the second light-emitting region R, and the third light-emitting region G. For example, the auxiliary layer 123 (that is commonly provided in the second light-emitting region R and the first light-emitting region B) may be used, and one fewer FMM may be used. Thus, a process may be simplified, and a failure rate may be reduced.

In FIG. 1, a natural frequency of 2 may be applied to green light, like to the red light. A wavelength of the red light may be greater than that of the green light, and a resonance distance adjusting layer of a red region may be thicker than that of a resonance distance adjusting layer of a green region. For example, the green light may require a shortest resonance distance, and the red light and the blue light may require a resonance distance that is longer than that of the green light. Accordingly, the common auxiliary layer 122 (having a thickness for adjusting a resonance distance of the green light) may be commonly provided in the first light-emitting region B, the second light-emitting region R, and the third light-emitting region G, and resonance distances for the red light and the blue light may be adjusted together by using only one auxiliary layer 123.

The capping layer 141 may be further provided on the second electrode 131. The capping layer 141 may be on the second electrode 131 and may protect the second electrode 131 from being damaged in a process of forming a thin-film encapsulation. The capping layer 141 may be formed using an organic material having a high refractive index in order to help improve light extraction efficiency of a light-emitting layer through refractive index matching. For example, the capping layer 141 may be formed by using at least one material of 8-quinolinolato lithium (Liq) or tris(8-hydroxy-quinolate)aluminum (Alq3).

In FIGS. 3 through 6, an order of forming the auxiliary layer 123, the first light-emitting layer 124B, the second light-emitting layer 124R, and the third light-emitting layer 124G is not limited thereto. For example, the third light-emitting layer 124G may be formed earlier than or prior to formation of the auxiliary layer 123, or the first light-emitting layer 124B and/or the second light-emitting layer 124R may be formed earlier than or prior to the formation of the third light-emitting layer 124G.

Although the organic light-emitting device is illustrated as a top-emission organic light-emitting device in FIG. 1, the embodiments are not limited thereto. The organic light-emitting device may be a bottom-emission organic light-emitting device for emitting light toward the substrate 100. In this case, the first electrode 111 may include a transparent electrode layer and a semi-transmissive layer (for forming a microcavity with the second electrode 131), and the second electrode 131 may be a reflective electrode. In an implementation, the organic light-emitting device may be a dual-emission organic light-emitting device for emitting light toward and away from the substrate 100, e.g., in both directions. In this case, the first electrode 111 may include a transparent electrode layer and a semi-transmissive layer for forming a microcavity with the second electrode 131, and the second electrode 131 may be a semi-transmissive electrode.

Although the organic light-emitting device is illustrated as being directly formed on the substrate 100 in FIG. 1, the embodiments are not limited thereto. For example, a thin-film transistor (TFT) array including a capacitor and a TFT (for driving the organic light-emitting device) may be formed on the substrate 100, and the organic light-emitting device may be formed to be connected to the TFT array. In an implementation, the first electrode 111 may further include a pixel-defining film (that covers an edge), and thus effective insulation between adjacent first electrodes 111 may be achieved.

FIGS. 8 through 10 illustrate cross-sectional views of organic light-emitting devices according to other embodiments.

The device illustrated in FIG. 8 is different from that of FIG. 1 in that the common auxiliary layer 122 may be between the second common layer 125 and light-emitting layers. In the device of FIG. 8, the common auxiliary layer 122 may use or may include a material that is different from that of FIG. 1. For example, in the device of FIG. 8, the common auxiliary layer 122 may include a suitable material for an ETL or an EITL.

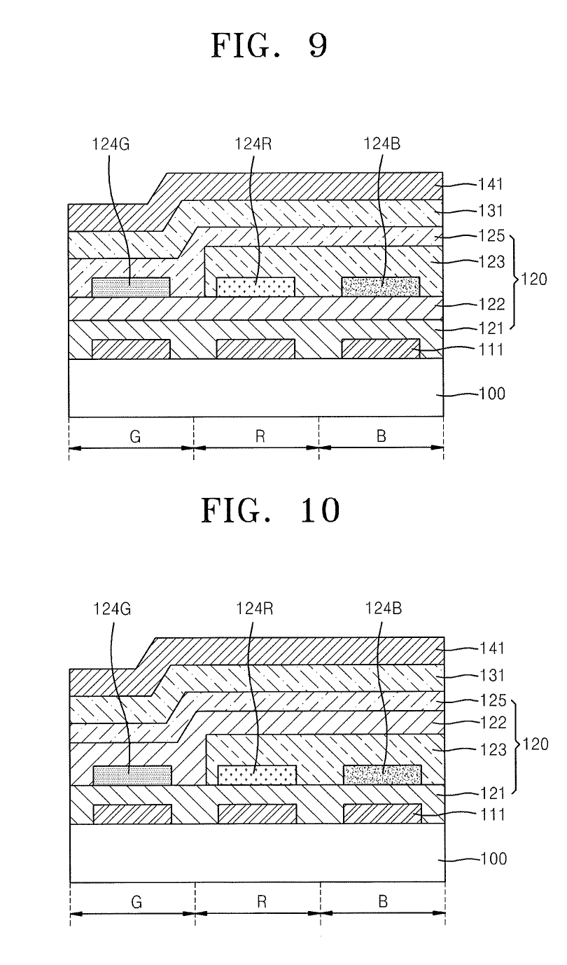

The device illustrated in FIG. 9 is different from that of FIG. 1 in that the auxiliary layer 123 may be between the second common layer 125 and the light-emitting layers. In the device of FIG. 9, the auxiliary layer 123 may use or may include a material that is different from that of FIG. 1. For example, in the device of FIG. 9, the auxiliary layer 123 may include a suitable material for an ETL or an EITL.

The device illustrated in FIG. 10 is different from that of FIG. 9 in that the common auxiliary layer 122 may be between the second common layer 125 and the light-emitting layers. In the device of FIG. 10, the common auxiliary layer 122 may use or may include a material that is different from that of FIG. 9. For example, in the device of FIG. 10, the common auxiliary layer may include a suitable material for an ETL or an EITL.

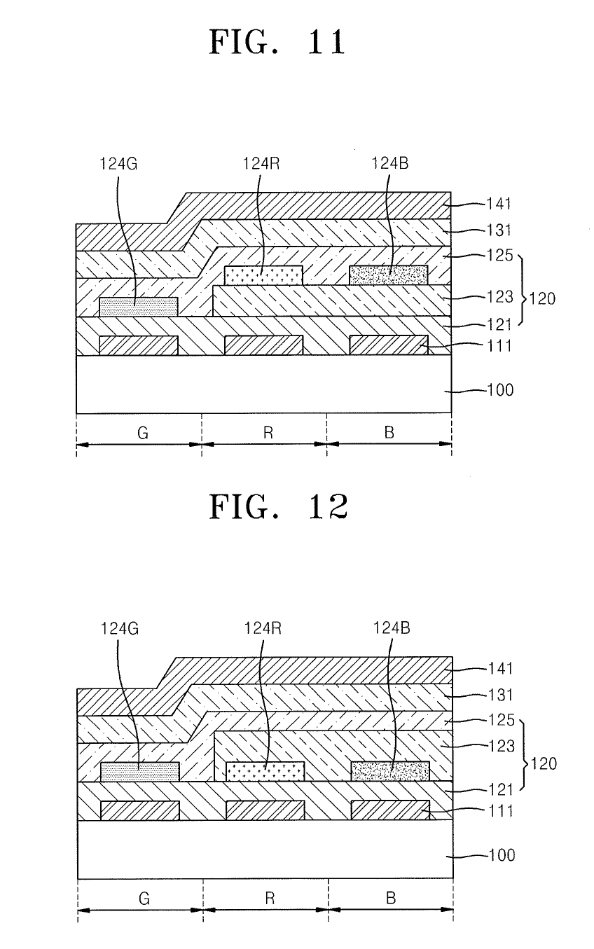

The device of FIG. 11 is different from that of FIG. 1 in that the common auxiliary layer 122 may be omitted. In order to achieve the same resonance distances as those in FIG. 1, thicknesses of the third light-emitting layer 124G, the auxiliary layer 123, the first light-emitting layer 124B, and the second light-emitting layer 124R may be changed. For example, in the device of FIG. 1, the third light-emitting layer 124G may have a thickness of about 200 Å to about 400 Å. In the device of FIG. 11, the third light-emitting layer 124G may have a thickness of about 600 Å to about 900 Å in consideration of or to compensate for a thickness of the omitted common auxiliary layer 122. When thicknesses of the first light-emitting layer 124B and the second light-emitting layer 124R are fixed, the auxiliary layer 123 may have a thickness of about 300 Å to 500 Å in the device of FIG. 1. In the device of FIG. 11, the auxiliary layer 123 may have a thickness of about 700 Å to 1,000 Å in consideration of or to compensate for a thickness of the omitted common auxiliary layer 122. Thicknesses of the first common layer 121 and the second common layer 125 may be changed in various ways, instead of thicknesses of the third light-emitting layer 124G, the auxiliary layer 123, the first light-emitting layer 124B, and the second light-emitting layer 124R, as long as the same resonance distances as those of the device of FIG. 1 are achieved.

The device of FIG. 12 is different from that of FIG. 9 in that the common auxiliary layer 122 may be omitted. In FIG. 12, in order to achieve the same resonance distances as those in the device FIG. 1, thicknesses of the third light-emitting layer 124G, the auxiliary layer 123, the first light-emitting layer 124B, the second light-emitting layer 124R, the first common layer 121, and the second common layer 125 may be changed in a similar manner to that in FIG. 11.

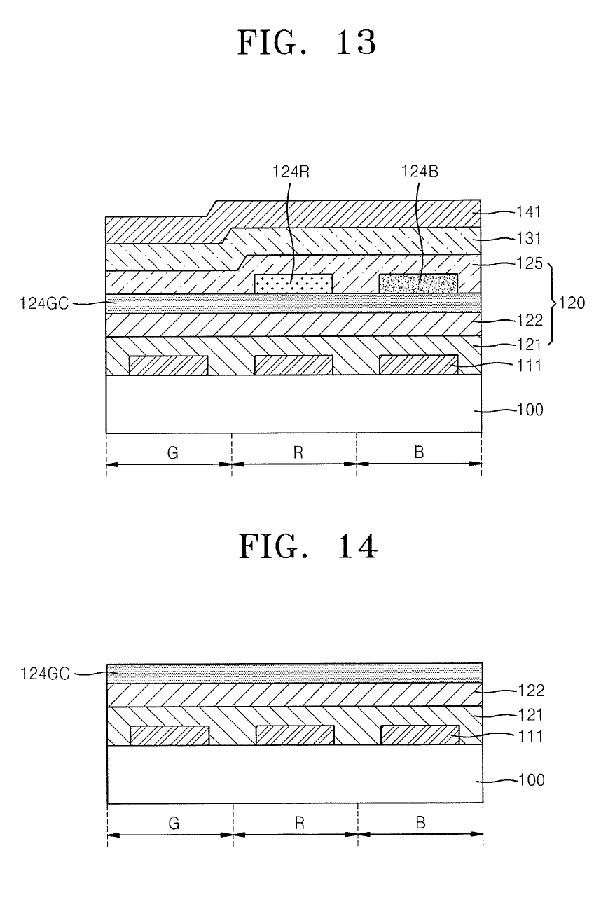

FIG. 13 illustrates a cross-sectional view of an organic light-emitting device according to another embodiment. FIGS. 14 through 17 illustrate cross-sectional views of stages in a method of manufacturing the organic light-emitting device of FIG. 13.

In FIG. 13, the first light-emitting region B, the second light-emitting region R, and the third light-emitting region G may be divided over the substrate 100. The first light-emitting region B may be a region that is included in a blue sub-pixel and emits blue light. The second light-emitting region R may be a region that is included in a red sub-pixel and emits red light. The third light-emitting region G may be a region that is included in a green sub-pixel and emits green light. Elements of the organic light-emitting device will be explained in accordance with operations of manufacturing the organic light-emitting device of FIG. 13.

The organic light-emitting device may be disposed over or on the substrate 100. The organic light-emitting device may include the first electrode 111 on the substrate 100, the intermediate layer 120 on the first electrode 111, the second electrode 131 on the intermediate layer 120 and facing the first electrode 111, and the capping layer 141 on the second electrode 131.

The first electrode 111 may be on the substrate 100, and may be independently patterned in each of the first light-emitting region B, the second light-emitting region R, and the third light-emitting region G. The first electrode 111 may include a reflective layer including, e.g., Ag, Mg, Al, Pt, Pd, Au, Ni, Nd, Ir, Cr, or a compound thereof, and a transparent or semi-transparent electrode layer on the reflective layer.

The transparent or semi-transparent electrode layer may include, e.g., any one of ITO, IZO, ZnO, In₂O₃, IGO, or AZO.

The intermediate layer 120 may be on the first electrode 111. The intermediate layer 120 may include, e.g., the first common layer 121 (on the first electrode 111 and being commonly formed in the first through third light-emitting regions B, R, and G), the common auxiliary layer 122 (on the first common layer 121), a third light-emitting layer 124GC (on the common auxiliary layer 122), the first light-emitting layer 124B (on the common third light-emitting layer 124GC to correspond to or in the first light-emitting region B), the second light-emitting layer 124R (on the common third light-emitting layer 124GC to correspond to or in the first light-emitting region B), and the second common layer 125 (covering the first light-emitting layer 124B, the second light-emitting layer 124R, and a part of the common third light-emitting layer 124GC).

The first common layer 121 may be, e.g., an HIL, an HTL, or an HITL. The HIL may enable holes to be easily injected into a light-emitting layer, and may use or may include, e.g., DNTPD, m-MTDATA, TDATA, 2T-NATA, NPB, PEDOT/PSS, Pani/DBSA, Pani/CSA, or PANI/PSS.

The HTL may enable the injected holes to be easily transported to the light-emitting layer, and may use or may include, e.g., TPD, NPB, or TCTA. The first common layer 121 may be commonly formed on the entire substrate 100 to cover the first electrode 111, e.g., without using an FMM, and may be formed by using any of various methods such as vacuum deposition, spin-coating, or casting.

Referring to FIG. 14, the common auxiliary layer 122 may be formed on the first common layer 121. The common auxiliary layer 122 may be an HTL or an HITL. Accordingly, the common auxiliary layer 122 may use or may include a suitable material for an HTL and an HITL. The common auxiliary layer 122 may be commonly formed on the entire substrate 100 to cover the first common layer 121, e.g., without using an FMM, and may be formed by using any of various methods such as vacuum deposition, spin-coating, or casting. The common auxiliary layer 122 may have a thickness of, e.g., about 400 Å to about 600 Å.

Referring to FIG. 14, the common third light-emitting layer 124GC may be formed in the first light-emitting region B, the second light-emitting region R, and the third light-emitting region G over or on the first common layer 121. The common third light-emitting layer 124GC may be a light-emitting layer that emits green light. The common third light-emitting layer 124GC may include a green host and a green dopant. Examples of the green host may include Alq3, CBP, PVK, ADN, TCTA, TPBI, TBADN, E3, and DSA. Examples of the green dopant may include Ir(ppy)₃, Ir(ppy)₂(acac), Ir(mppy)₃, and C545T. The common third light-emitting layer 124GC may be commonly formed on the entire substrate 100 to cover the first common layer 121, e.g., without using an FMM, and may be formed by using any of various methods such as vacuum deposition, spin-coating, or casting.

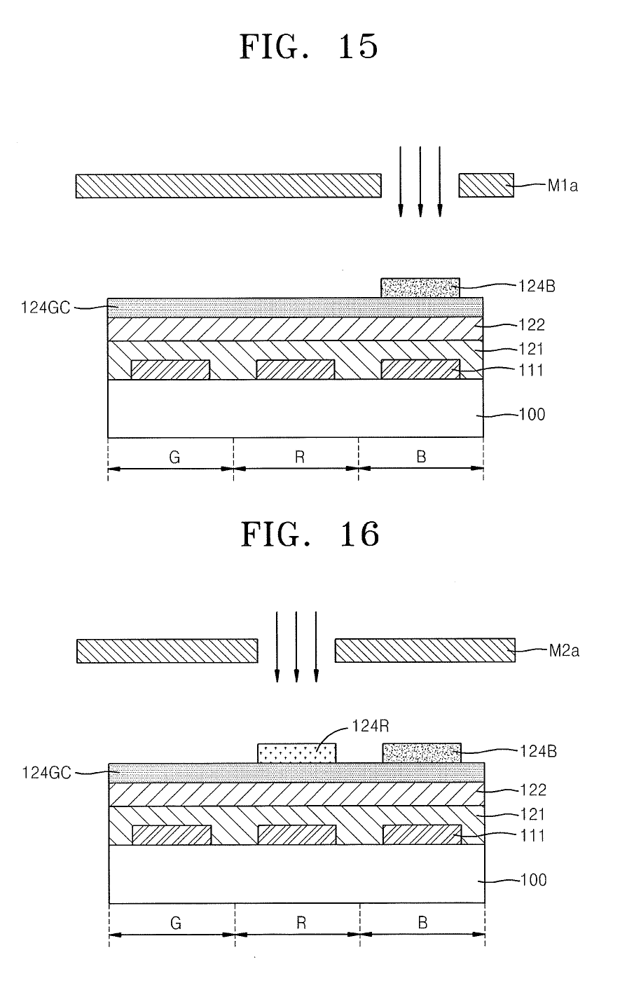

Referring to FIG. 15, the first light-emitting layer 124B may be formed in the first light-emitting region B over or on the common third light-emitting layer 124GC. The first light-emitting layer 124B may be a light-emitting layer that emits blue light. The first light-emitting layer 124B may include a blue host and a blue dopant. Examples of the blue host may include Alq3, CBP, PVK, ADN, TCTA, TPBI, TBADN, E3, and DSA. Examples of the blue dopant may include F2lrpic, (F2ppy)₂Ir(tmd), Ir(dfppz)₃, ter-fluorene, 4,4′-bis(4-diphenylaminostyryl)biphenyl (DPAVBi), and 2,5,8,11-tetra-t-butylperylene (TBPe). The first light-emitting layer 124B may be formed only in the first light-emitting region B by using vacuum deposition using a 1a FMM Mla. The first light-emitting layer 124B may have a thickness of, e.g., about 200 Å to about 400 Å.

Referring to FIG. 16, the second light-emitting layer 124R may be formed in the second light-emitting region R over or on the common third light-emitting layer 124GC. The second light-emitting layer 124R may be a light-emitting layer that emits red light. The second light-emitting layer 124R may include a red host and a red dopant. Examples of the red host may include Alq3, CBP, PVK, ADN, TCTA, TPBI, TBADN, E3, and DSA, like the blue host. Examples of the red dopant may include Ir(piq)₃, Btp₂Ir(acac), Ir(piq)₂(acac), Ir(2-phq)₂(acac), Ir(2-phq)₃, Ir(flq)₂(acac), Ir(fliq)₂(acac), DCM, and DCJTB. The second light-emitting layer 124R may be formed only in the second light-emitting region R by using vacuum deposition using a 2a FMM M2a. The second light-emitting layer 124R may have a thickness of, e.g., about 200 Å to about 400 Å.

Referring to FIG. 17, the second common layer 125 may be formed to cover the first light-emitting layer 124B, the second light-emitting layer 124R, and at least a part of the common third light-emitting layer 124GC. When the second electrode 131 functions as a cathode, the second common layer 125 may be an EIL, an ETL, or an EITL. The EIL may enable electrons to be easily injected into a light-emitting layer, and may use or may include a suitable material for an EIL, e.g., LiF, NaCl, CsF, Li₂O, or BaO. The ETL may enable the injected electrons to be easily transported to the light-emitting layer, and may use or may include suitable materials, e.g., Alq3, BCP, Bphen, TAZ, NTAZ, tBu-PBD, Bebq₂, or ADN. The second common layer 125 may be commonly formed on the entire substrate 100 to cover light-emitting layers, e.g., without using an FMM, and may be formed by using any of various methods such as vacuum deposition, spin-coating, or casting.

The second electrode 131 may be disposed on the intermediate layer 120. The second electrode 131 may be a semi-transmissive electrode, may include at least one material selected from the group of Ag, Al, Mg, Li, Ca, Cu, LiF/Ca, LiF/Al, Mg:Ag, and Ca:Ag, and/or may be formed as a thin film having a thickness of several nm to tens of nm.

In the present embodiment, the organic light-emitting device may be a top-emission organic light-emitting device for emitting light away from the substrate 100.

The device of FIG. 13 is different from that of FIG. 1 in that the common third light-emitting layer 124GC (that is a green common light-emitting layer) may be used. Accordingly, the third light-emitting layer 124G and the auxiliary layer 123 may not need to be additionally formed, and the number of FMMs used to form the device may be reduced by two, when compared to the device of FIG. 1. The common third light-emitting layer 124GC may function not only as a light-emitting layer that emits green light in the third light-emitting region G, but also as the auxiliary layer 123 that is used to have or adjust resonance distances in the first light-emitting region B and the second light-emitting region R. For example, a thickness of the common third light-emitting layer 124GC may need to be great enough to have a resonance distance for green light and also have a resonance distance for red light and blue light. Also, the common third light-emitting layer 124GC may further include a material for efficiently transmitting holes to the first light-emitting layer 124B and the second light-emitting layer 124R.

The capping layer 141 may be further disposed on the second electrode 131. The capping layer 141 may be on the second electrode 131 and may protect the second electrode 131 from being damaged in a process of forming a thin-film encapsulation. The capping layer 141 may be formed by using an organic material having a high refractive index in order to help improve light extraction efficiency of a light-emitting layer through refractive index matching. For example, the capping layer 141 may be formed by using at least one material of Liq and Alq3.

In FIGS. 14 through 17, an order of forming the first light-emitting layer 124B and the second light-emitting layer 124R is not limited thereto, and the second light-emitting layer 124R may be formed earlier than the first light-emitting layer 124B.

Although the organic light-emitting device is illustrated as being a top-emission organic light-emitting device in FIG. 1 and FIG. 13, the embodiments are not limited thereto. For example, the organic light-emitting device may be a bottom-emission organic light-emitting device or a dual-emission organic light-emitting device.

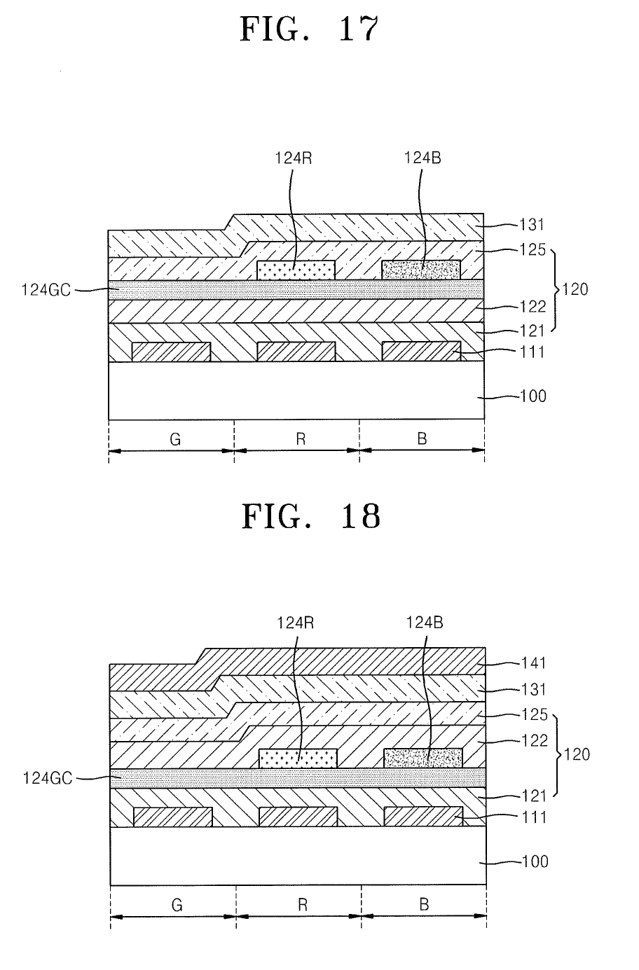

FIGS. 18 through 22 illustrate cross-sectional views of organic light-emitting devices according to other embodiments.

The device of FIG. 18 is different from that of FIG. 13 in that the common auxiliary layer 122 may be between the second common layer 125 and the light-emitting layers. The common auxiliary layer 122 of FIG. 18 may use or may include a material that is different from that of the device FIG. 13. For example, the common auxiliary layer 122 of FIG. 18 may include a suitable material for an ETL or an EITL.

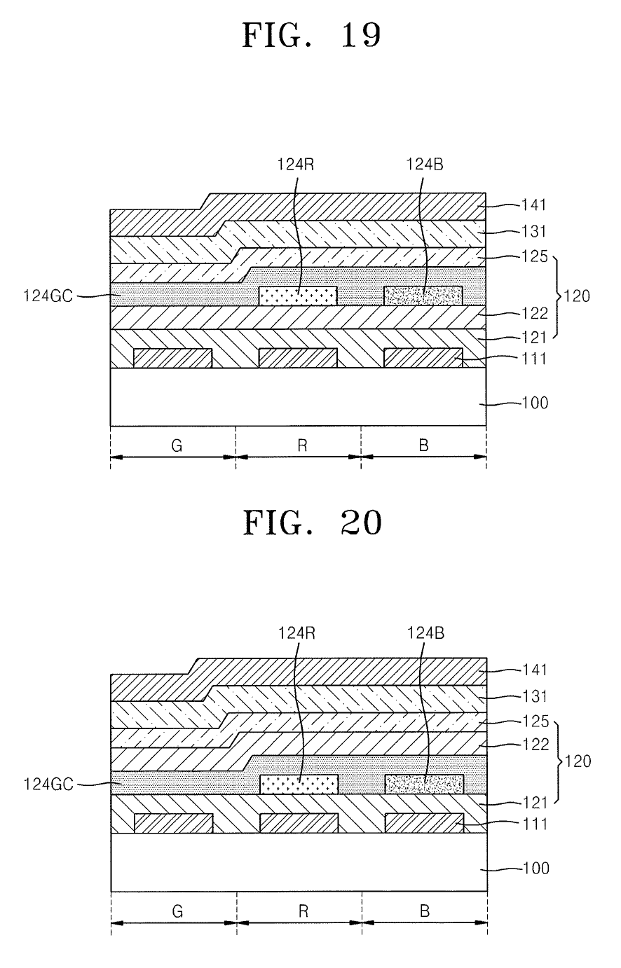

The device of FIG. 19 is different from that of FIG. 13 in that the common third light-emitting layer 124GC may be between the second common layer 125 and the light-emitting layers. The common third light-emitting layer 124GC of FIG. 19 may use or may include a material that is different from that of FIG. 13. For example, the common third light-emitting layer 124GC of FIG. 19 may include a suitable material for more efficiently transporting electrons to the first light-emitting layer 124B and the second light-emitting layer 124R.

The device of FIG. 20 is different from that of FIG. 19 in that the common auxiliary layer 122 may be between the second common layer 125 and the light-emitting layers. The common auxiliary layer 122 of FIG. 20 may use or may include a material that is different from that of FIG. 19. For example, the common auxiliary layer 122 of FIG. 20 may include a material that is suitable for an ETL or an EITL.

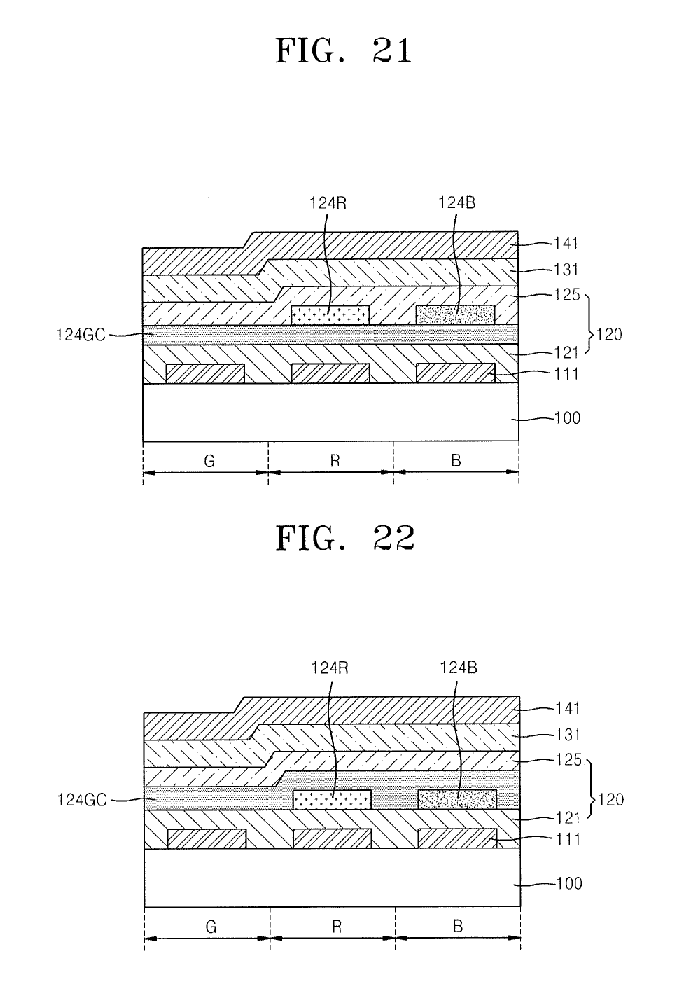

The device of FIG. 21 is different from that of FIG. 13 in that the common auxiliary layer 122 may be omitted. Thicknesses of the common third light-emitting layer 124GC, the first light-emitting layer 124B, and the second light-emitting layer 124R may be changed in various ways as long as the same resonance distances as those in FIG. 21 or FIG. 13 may be achieved. Also, thicknesses of the first common layer 121 and the second common layer 125 may be changed in various ways.

The device of FIG. 22 may be different from that of FIG. 19 in that the common auxiliary layer 122 may be omitted. Thicknesses of the common third light-emitting layer 124GC, the first light-emitting layer 124B, and the second light-emitting layer 124R may be changed in a similar manner to that in FIG. 21 in order to have the same resonance distances as those in FIG. 19. Also, thicknesses of the first common layer 121 and the second common layer 125 may be changed in various ways.

By way of summation and review, an organic light-emitting device may include a plurality of pixels, and each of the plurality of pixels may include a red light-emitting region, a green light-emitting region, and a blue light-emitting region.

As described above, an organic light-emitting device according to an embodiment may reduce a number of FMMs that are used during manufacturing, thereby improving productivity.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. An organic light-emitting device, comprising:
a substrate;
a plurality of first electrodes on the substrate in a first light-emitting region, a second light-emitting region, and a third light-emitting region;
a first common layer on the substrate, the first common layer covering the plurality of first electrodes;
a first light-emitting layer in the first light-emitting region and on the first common layer;
a second light-emitting layer in the second light-emitting region and on the first common layer;
a third light-emitting layer in the third light-emitting region and on the first common layer;
a second common layer that is commonly disposed on the first light-emitting layer, the second light-emitting layer, and the third light-emitting layer;
a second electrode on the second common layer; and
an auxiliary layer that is commonly disposed only in the first light-emitting region and the second light-emitting region between the first common layer and the second common layer.

2. The organic light-emitting layer as claimed in claim 1, wherein the auxiliary layer is between the first light-emitting layer and the first common layer and between the second light-emitting layer and the first common layer.

3. The organic light-emitting layer as claimed in claim 1, wherein the auxiliary layer is between the first light-emitting layer and the second common layer and between the second light-emitting layer and the second common layer.

4. The organic light-emitting layer as claimed in claim 1, wherein the third light-emitting layer and the auxiliary layer are commonly formed on the same layer.

5. The organic light-emitting layer as claimed in claim 4, wherein the third light-emitting layer and the auxiliary layer that are commonly formed are disposed between the first, second light-emitting layers and the first common layer.

6. The organic light-emitting device as claimed in claim 4, wherein the third light-emitting layer and the auxiliary layer that are commonly formed are disposed between the first, second light-emitting layers and the second common layer.

7. The organic light-emitting device as claimed in claim 1, further comprising a common auxiliary layer on the first common layer, the common auxiliary electrode being between the first common layer and the first to third light-emitting layers.

8. The organic light-emitting device as claimed in claim 1, further comprising a common auxiliary layer under the second common layer, the common auxiliary electrode being between the second common layer and the first to third light-emitting layers.

9. The organic light-emitting device as claimed in claim 1, wherein the first light-emitting layer and the second light-emitting layer have the same thickness.

10. The organic light-emitting device as claimed in claim 1, wherein the first light-emitting region is a blue light-emitting region, the second light-emitting region is a red light-emitting region, and the third light-emitting region is a green light-emitting region.

11. A method of manufacturing an organic light-emitting device, the method comprising:
providing a substrate;
forming a plurality of first electrodes on the substrate in a first light-emitting region, a second light-emitting region, and a third light-emitting region of the substrate;
forming a first common layer on the substrate such that the first common layer covers the first electrodes;
forming a first light-emitting layer in the first light-emitting region and on the first common layer using a first mask;
forming a second light-emitting layer in the second light-emitting region and on the first common layer using a second mask;
forming a third light-emitting layer in the third light-emitting region and on the first common layer using a third mask;
commonly forming a second common layer on the first light-emitting layer, the second light-emitting layer, and the third light-emitting layer;
forming a second electrode on the second common layer; and
commonly forming an auxiliary layer between the first common layer and the second common layer and only in the first light-emitting region and the second light-emitting region using a fourth mask.

12. The method as claimed in claim 11, wherein the auxiliary layer is formed between the first light-emitting layer and the first common layer and between the second light-emitting layer and the first common layer.

13. The method as claimed in claim 11, wherein the auxiliary layer is formed between the first light-emitting layer and the second common layer and between the second light-emitting layer and the second common layer.

14. The method as claimed in claim 11, further comprising forming a common auxiliary layer after forming the first common layer such that the common auxiliary layer is between the first common layer and the first to third light-emitting layers.

15. The method as claimed in claim 11, further comprising forming a common auxiliary layer prior to forming the second common layer such that the common auxiliary layer is between the second common layer and the first to third light-emitting layers.

16. A method of manufacturing an organic light-emitting device, the method comprising:
providing a substrate;
forming a plurality of first electrodes on the substrate in a first light-emitting region, a second light-emitting region, and a third light-emitting region;
forming a first common layer on the substrate such that the first common layer covers the first electrodes;
forming a first light-emitting layer in the first light-emitting region and on the first common layer using a first mask;
forming a second light-emitting layer in the second light-emitting region and on the first common layer using a second mask;
commonly forming a second common layer on the first light-emitting layer and the second light-emitting layer;
forming a second electrode on the second common layer; and
commonly forming a common third light-emitting layer in the first light-emitting region, the second light-emitting region, and the third light-emitting region between the first common layer and the second common layer.

17. The method as claimed in claim 16, wherein the common third light-emitting layer is formed prior to forming the first light-emitting layer and the second light-emitting layer such that the common third light-emitting layer is between the first common layer and the first light-emitting layer and between the first common layer and the second light-emitting layer.

18. The method as claimed in claim 16, wherein the common third light-emitting layer is formed after forming the first light-emitting layer and the second light-emitting layer such that the common third light-emitting layer is between the second common layer and the first light-emitting layer and between the second common layer and the second light-emitting layer.

19. The method as claimed in claim 16, further comprising forming a common auxiliary layer after forming the first common layer such that the common auxiliary layer is between the first common layer and the common third light-emitting layer.

20. The method as claimed in claim 16, further comprising forming a common auxiliary layer prior to forming the second common layer such that the common auxiliary layer is between the second common layer and the common third light-emitting layer.
